(19) United States
(12) Patent Application Publication
(10) Pub. No.: US 2020/0118940 A1
(43) Pub. Date: Apr. 16, 2020

(54) DIE WITH BUMPER FOR SOLDER JOINT RELIABILITY

(71) Applicant: Intel Corporation, Santa Clara, CA (US)

(72) Inventors: Krishna Hemanth VEPAKOMMA, El Dorado Hills, CA (US); Yi XU, Folsom, CA (US)

(21) Appl. No.: 16/160,191

(22) Filed: Oct. 15, 2018

(51) Int. Cl. H01L 23/00

(52) U.S. Cl. CPC H01L 23/562; H01L 24/49; H01L 24/06; H01L 2924/351; H01L 2224/48091; H01L 2224/4905; H01L 2924/14

(57) ABSTRACT

Embodiments disclosed herein include an electronic package and methods of forming an electronic package. In an embodiment, the electronic package comprises a package substrate and a die on the package substrate. In an embodiment, the die is attached to the package substrate by a die attach film. In an embodiment, the electronic package further comprises a sidewall bumper surrounding sidewalls of the die. In an embodiment, the electronic package further comprises a mold layer over the die and the package substrate.

TECHNICAL FIELD

Embodiments of the present disclosure relate to electronic packaging, and more particularly, to electronic packages with dies that include a bumper for improved solder joint reliability (SJR).

### BACKGROUND

Solder joint reliability (SJR) is an important metric for ensuring high reliability of electronic packages. In many instances SJR is negatively impacted by coefficient of thermal expansion (CTE) mismatches between semiconductor dies, molding compounds, and package substrates. As more dies are added to the electronic package (e.g., to form high density memory packages), the CTE mismatches become increasingly problematic.

Current solutions to reduce the CTE mismatch and improve SJR include adding a spacer below the stack of semiconductor dies. However, the inclusion of a spacer has several drawbacks. For example, since the spacer is typically a semiconductor material (e.g., silicon), the cost associated with adding the spacer is relatively high. Additionally, spacers add process risk during die attach and wire bonding operations. Furthermore, spacers introduce a risk of die to mold material delamination. The inclusion of a spacer below the stack of semiconductor dies also increases the electronic package Z-height.

### BRIEF DESCRIPTION OF THE DRAWINGS

FIG. 1 is a cross-sectional illustration of an electronic package with a plurality of stacked dies that each include a bumper, in accordance with an embodiment.

FIG. 2A is a perspective view illustration of a die with a bumper, in accordance with an embodiment.

FIG. 2B is a cross-sectional illustration of the electronic package in FIG. 2A, in accordance with an embodiment.

FIG. 3A is a perspective view illustration of a wafer with a plurality of dies on carrying tape, in accordance with an embodiment.

FIG. 3B is a perspective view illustration of a plurality of singulated dies on the carrying tape, in accordance with an embodiment.

FIG. 3C is a perspective view illustration after the carrying tape is expanded to increase the spacing between the dies, in accordance with an embodiment.

FIG. 3D is a perspective view illustration after a bumper layer is deposited around the dies, in accordance with an embodiment.

FIG. 3E is a perspective view illustration of the dicing lines through the bumper layer between the dies, in accordance with an embodiment.

FIG. 3F is a perspective view illustration of a plurality of singulated dies where each die includes a bumper, in accordance with an embodiment.

FIG. 3G is a perspective view illustration of a plurality of stacked dies with wire bonds on a package substrate, in accordance with an embodiment.

FIG. 3H is a perspective view illustration of the plurality of stacked dies after a second bumper layer is formed over top surfaces of the dies, in accordance with an embodiment.

FIG. 4 is a schematic of a computing device built in accordance with an embodiment.

### EMBODIMENTS OF THE PRESENT DISCLOSURE

Described herein are electronic packages with dies that include a bumper and methods of forming such electronic packages. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, solder joint reliability (SJR) is negatively affected by the coefficient of thermal expansion (CTE) mismatches between the semiconductor dies, the package substrate, and the molding compound. Accordingly, embodiments disclosed herein include a bumper layer that surrounds the semiconductor dies. The bumper layer is a low modulus material that allows for the strain resulting from the CTE mismatches to be absorbed. That is, the bumper layer decouples the dies from the mold compound and relieves the strain that would otherwise be transferred to the solder joints. Accordingly, embodiments disclosed herein improve SJR since the strains on the solder joints are minimized.

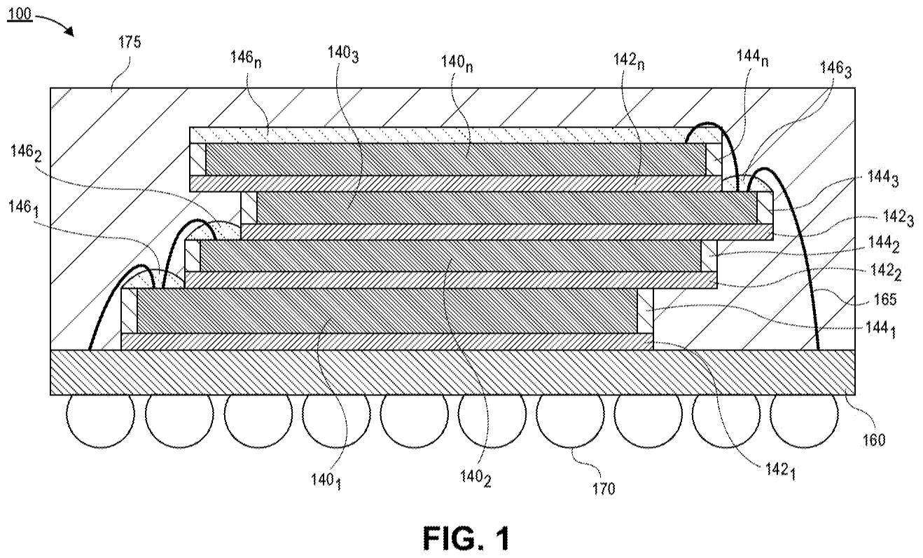

Referring now to FIG. 1, a cross-sectional illustration of an electronic package 100 is shown, in accordance with an embodiment. In an embodiment, the electronic package 100 may comprise a package substrate 160. Solder balls 170 may be attached to a surface of the package substrate 160 in some embodiments. In an embodiment, a die stack comprising one or more dies 140 may be mechanically coupled to the package substrate 160. In the illustrated embodiment, four dies 140₁-140ₙ are shown, but it is to be appreciated that any number of dies 140 may be included in the die stack. In an embodiment, the dies 140 may be electrically coupled to the package substrate 160 by wire bonds 165. In an embodiment, the dies 140₁₋ₙ may be any type of die, such as one or more of memory dies, processor dies, communication dies, graphics processing dies, or the like.

In an embodiment, a mold compound 175 may be formed over the package substrate 160 and the one or more dies 140₁₋ₙ. The mold compound 175 may have a CTE that is different than the CTE of the dies 140. Accordingly, during temperature cycling, the differences in CTE between the dies 140, the mold compound 175, and the package substrate 160 may result in strains being induced in the electronic package 100. If left unaccounted for, the strains may result in SJR issues for the solder balls 170.

Accordingly, embodiments disclosed herein include strain absorbing layers surrounding the one or more dies 140. The strain absorbing layers comprise materials that have a Young's modulus that is lower than the surrounding materials. That is, the Young's modulus of the strain absorbing layers may be less than the Young's moduli of the dies 140, the mold compound 175, and the package substrate 160. Since the Young's modulus of the strain absorbing layers is less than that of the surrounding materials, the strain absorbing layer will preferentially absorb the strains induced in the electronic package 100

In an embodiment, the strain absorbing layers may comprise one or more of a die attach film (DAF) 142, a sidewall bumper 144, and a top surface bumper 146. For example, in FIG. 1 each of the dies 140₁₋ₙ include a DAF 142₁₋ₙ along a bottom surface and a sidewall bumper 144₁₋ₙ surrounding sidewalls of the dies 140₁₋ₙ . In an embodiment, the top surface bumpers 146₁₋ₙ may cover a portion of the top surface of the die 140 that is not covered by a subsequent DAF 142 (e.g., a top surface of the first die 140₁ is covered by DAF 142₂ and a top surface bumper 146₁, and a top surface of the fourth die 140ₙ is entirely covered by a top surface bumper 146ₙ). In an embodiment, the top surface bumpers 146 may have non-planar top surfaces. The non-planar top surface may be attributable to the deposition process used to deposit the top surface bumpers 146, as will be described in greater detail below.

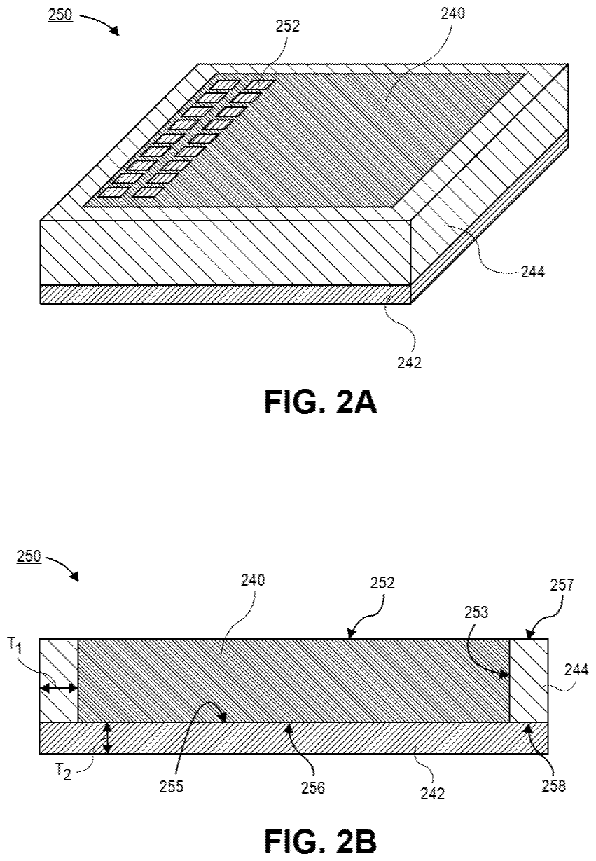

Referring now to FIG. 2A, a perspective view illustration of a semiconductor die module 250 that may be included in an electronic package (e.g., electronic package 100) is shown, in accordance with an embodiment. In an embodiment, the semiconductor die module 250 may comprise a DAF 242, a die 240, and a sidewall bumper 244 surrounding the die 240. In an embodiment, the sidewall bumper 244 may entirely surround a perimeter of the die 240. That is, the entire sidewall surface of the die 240 may be covered by the sidewall bumper in some embodiments. The DAF 242 may be a layer that underlies both the die 240 and the sidewall bumper 244. That is, the sidewall bumper 244 may be supported by the DAF 242. In an embodiment, the die 240 may comprise a plurality of contacts 252. The contacts 252 may be suitable for wire bonding, or the like.

In an embodiment, the DAF 244 may be any suitable material for adhering the die 240 to an underlying substrate. In a particular embodiment, the DAF 244 may have a Young's modulus that is less than the Young's moduli of the die 240, the mold compound, and the package substrate. In an embodiment, the sidewall bumper 244 may be a material that has Young's modulus that is less than the Young's moduli of the die 240, the mold compound, and the package substrate. For example, the sidewall bumper 244 may be an epoxy.

Referring now to FIG. 2B, a cross-sectional illustration of the semiconductor die module 250 is shown, in accordance with an embodiment. As shown, the DAF 242 is an underlying layer on which the die 240 and the sidewall bumper 244 are supported. For example, a bottom surface 258 of the sidewall bumper 244 and a bottom surface 255 of the die 240 may be supported by a top surface 256 of the DAF 242. In an embodiment, the bottom surface 255 of the die 240 and the bottom surface 258 of the sidewall bumper 244 may be substantially coplanar since they both rest on the same surface 256 of the DAF 242. In an embodiment, a top surface 257 of the sidewall bumper 244 may be substantially coplanar with a top surface 252 of the die 240. Particularly, embodiments include a sidewall bumper 244 that is not above the top surface 252 of the die 240. This ensures that the material used to form the sidewall bumper 244 does not extend over the top surface 252 of the die 240. Accordingly, the contact pads 252 (not visible in FIG. 2B) are not inadvertently covered by the sidewall bumper 244. In an embodiment, the entire sidewall surface 253 of the die 240 may be covered by the sidewall bumper 244.

In an embodiment, the sidewall bumper 244 may have a first thickness T₁ and the DAF may have a second thickness T₂. As shown, the thicknesses T₁ and T₂ may refer to a thickness in a direction perpendicular from the surface of the die 240 on which the layer is formed. In an embodiment, the first thickness T₁ and the second thickness T₂ may be sufficient to mechanically decouple the die 240 from surrounding materials (e.g., the mold compound and package substrate). In an embodiment, the first thickness T₁ and the second thickness T₂ may be approximately 15 microns or greater, 25 microns or greater, or 50 microns or greater. In an embodiment, the first thickness T₁ may be different than the second thickness T₂. For example, the first thickness T₁ may be greater than the second thickness T₂.

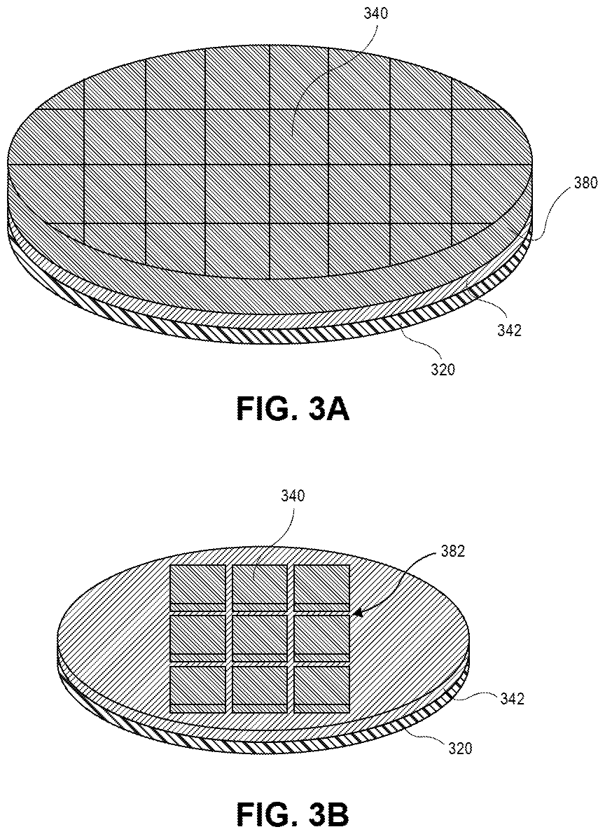

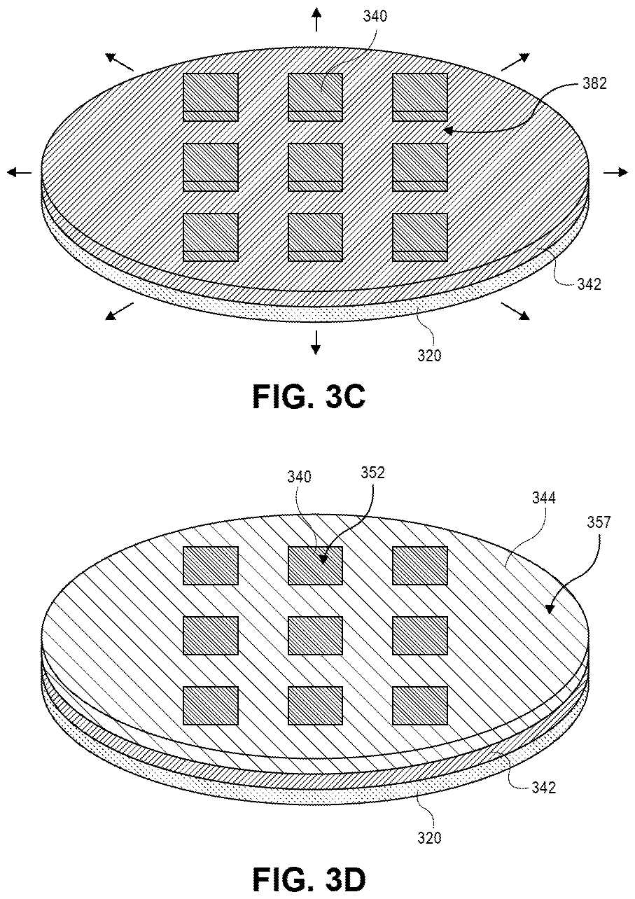

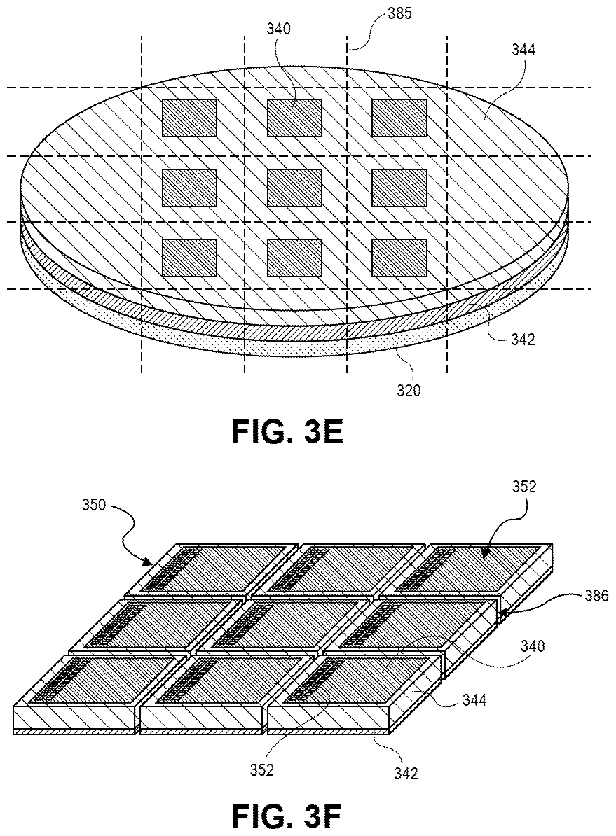

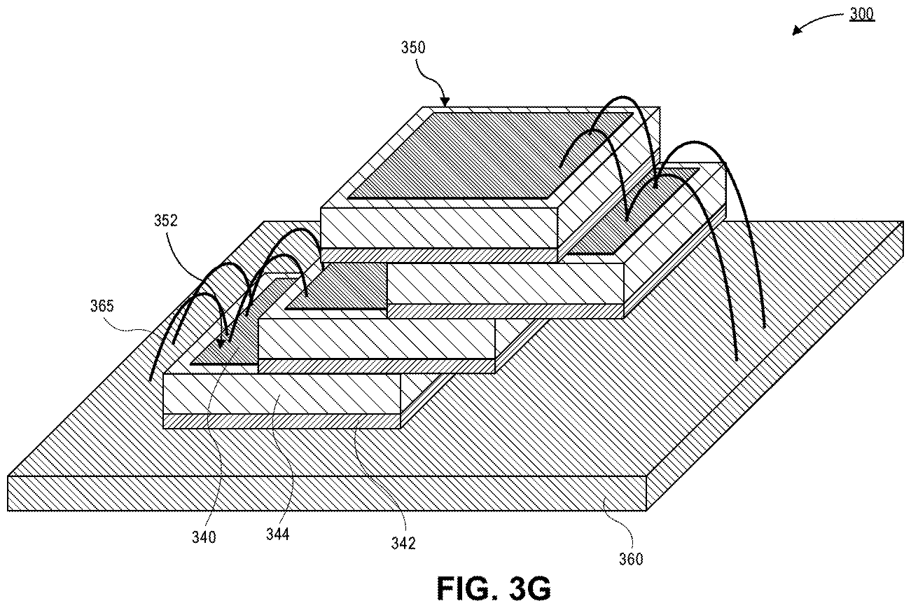

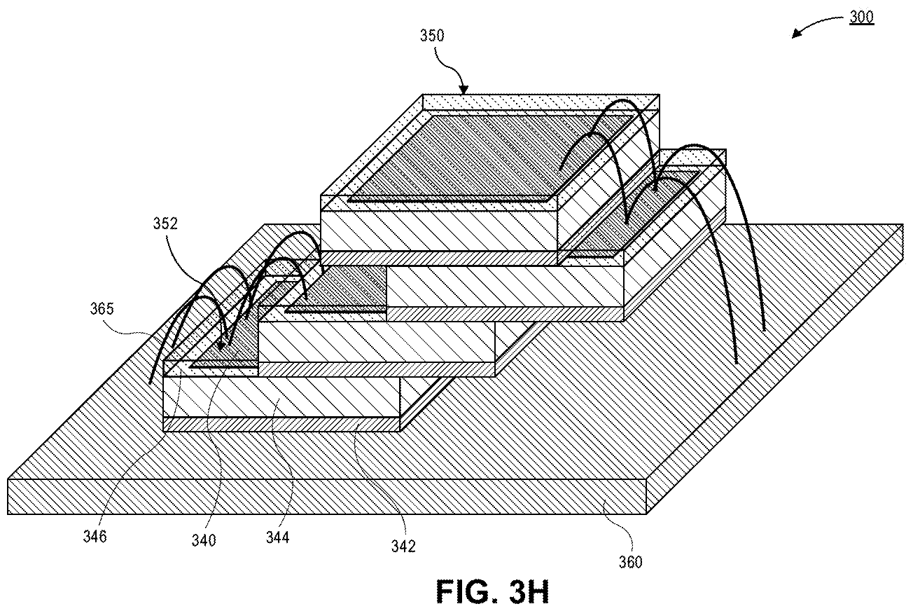

Referring now to FIGS. 3A-3H, a series of perspective view illustrations that depict a process for forming an electronic package is shown, in accordance with an embodiment.

Referring now to FIG. 3A, a perspective view illustration of a semiconductor wafer 380 with a plurality of dies 340 is shown, in accordance with an embodiment. In an embodiment, the semiconductor wafer 380 may have any form factor (e.g., 300 mm or the like) on which a plurality of dies 340 are fabricated. For example, the plurality of dies may be memory dies, processor dies, communication dies, graphics dies, or the like. In an embodiment, the semiconductor wafer 380 may be positioned over a DAF 342. In an embodiment, the DAF 342 may be supported by a carrying tape 320. The carrying tape 320 may be any suitable tape on which the semiconductor wafer may be diced (e.g., with laser dicing or the like).

Referring now to FIG. 3B, a perspective view illustration after the semiconductor wafer 380 has be diced is shown, in accordance with an embodiment. As shown, the semiconductor wafer 380 may be diced along saw streets 382 between the dies 340. In FIG. 3B only a portion of the dies 340 are shown for simplicity. It is to be appreciated that tens or hundreds of singulated dies 340 may remain on the DAF 342 after the dicing process.

Referring now to FIG. 3C, a perspective view illustration after the carrying tape 320 is stretched is shown, in accordance with an embodiment. In an embodiment, the carrying tape 320 may be stretched radially, as indicated by the arrows. The stretching of the carrying tape 320 results in a width of the saw streets 382 between the dies 340 being increased. That is, the spacing between the dies 340 is increased by stretching the carrying tape 320.

Referring now to FIG. 3D, a perspective view illustration after a sidewall bumper material 344 is deposited around the dies 340 is shown, in accordance with an embodiment. As shown, the sidewall bumper material 344 may be sufficient to completely cover the sidewall surfaces of the dies 340 while leaving a top surface 352 of the dies exposed. In an embodiment, the sidewall bumper material 344 may be deposited with a spin coating process, or any other deposition process. As shown in FIG. 3D, the top surfaces 352 of the dies 340 are substantially coplanar with a top surface 357 of the sidewall bumper material 344. However, it is to be appreciated that in some embodiments, the top surface 357 of the sidewall bumper material 344 may be below the top surfaces 352 of the dies 340. That is, in some embodiments portions of the sidewalls of the dies 340 may be exposed. In an embodiment, the sidewall bumper material 344 may be cured.

Referring now to FIG. 3E, a perspective view illustration after the sidewall bumper material 344 has been cured and the locations of saw streets 385 are illustrated is shown, in accordance with an embodiment. As shown, saw streets 385 may be formed in rows and columns between the dies 344. The location of the saw streets 385 ensures that portions of the sidewall bumper material 344 remains behind along the entire perimeter of the individual dies 340 after dicing.

Referring now to FIG. 3F, a perspective view illustration of a plurality of diced semiconductor die modules 350 are shown, in accordance with an embodiment. As shown, the semiconductor die modules 350 may be spaced apart by gaps 386 where the sidewall bumper material 344 has been removed with the dicing process. In an embodiment, each of the semiconductor die modules 350 may comprise a DAF 342, a die 340, and a sidewall bumper 344 that covers the sidewalls of the die 340. In an embodiment, the exposed top surface 352 of the dies 340 may also comprise contacts (e.g., for wire bonding). In the illustrated embodiment, the sidewall surfaces of the sidewall bumpers 344 may be substantially vertical. For example, when the dicing is implemented with a saw, the sidewalls may be substantially vertical. If other dicing methods are used (e.g., laser dicing), then the sidewalls of the sidewall bumpers 344 may be tapered.

Referring now to FIG. 3G, a perspective view illustration of an electronic package 300 with a plurality of semiconductor die modules 350 with sidewall bumpers 344 stacked on a package substrate 360 is shown, in accordance with an embodiment. In an embodiment, a plurality of semiconductor die modules 350 may be placed in a stack on the package substrate 360 with a pick-and-place process, or the like. The DAFs 342 may mechanically couple the dies 340 to each other and to the package substrate 360. In an embodiment, the semiconductor die modules 350 may be offset in order to provide access to conductive pads (not shown) on the top surface 352 of the dies 340. The conductive pads may be electrically coupled to the package substrate 360 with wire bonds 365 or the like.

Referring now to FIG. 3H, a perspective view illustration of an electronic package 300 after a top surface bumper 346 is formed over the semiconductor die modules 350. In an embodiment, the top surface bumper 346 may be any suitable material that has a Young's modulus that is less than the Young's moduli of the die 340, the package substrate 360, and the mold compound (not shown in FIG. 3H). For example, the top surface bumper 346 may be epoxy or the like. In an embodiment, the top surface bumper 346 may be the same material as the sidewall bumpers 344.

In an embodiment, the top surface bumper 346 may cover portions of the top surface 352 of the dies 340 that are not covered by an overlying DAF 344. For example, a first portion of the top surface 352 of the bottommost die 340 is covered by the top surface bumper 346 and a second portion of the top surface 352 of the bottommost die 340 is covered by a DAF 344. In an embodiment, the entire top surface 352 of the uppermost die 340 may be covered by a top surface bumper 346. In an embodiment, the top surface bumpers 346 may be deposited with any suitable paste dispensing process (e.g., ink jetting or the like). Depending on the process used to dispense the top surface bumpers 346, the top surface of the top surface bumpers 346 may be non-planar (e.g., similar to what is shown in FIG. 1). In other embodiments, the top surface of the top surface bumpers 346 may be substantially planar. In an embodiment, the top surface bumpers 346 may be cured.

After the top surface bumpers 346 are applied, each of the dies 340 in the electronic package 300 may be entirely surrounded by a strain absorbing material. For example, the dies 340 may have bottom surfaces that are covered by a DAF 344, sidewall surfaces that are covered by the sidewall bumpers 344, and top surfaces that are covered with a top surface bumper 346 or a top surface bumper 346 and a DAF 344. A mold compound may then be applied over the electronic package 300 to form an electronic package similar to electronic package 100 shown in FIG. 1. Accordingly, the dies 340 may be mechanically decoupled from the mold compound and the package substrate. As such, strains arising from CTE mismatches in materials may be absorbed by the strain absorbing layers (e.g., DAF 344, sidewall bumpers 344, and top surface bumpers 346) instead of being transferred to the solder balls, and SIR is improved for the electronic package 300.

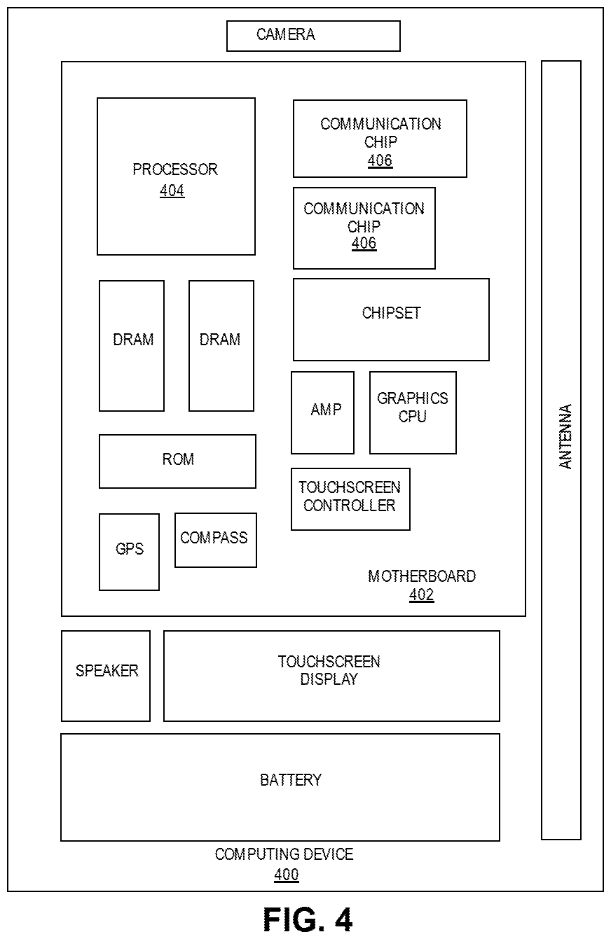

FIG. 4 illustrates a computing device 400 in accordance with one implementation of the invention. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In some implementations of the invention, the integrated circuit die of the processor may comprise strain absorbing layers surrounding surfaces of the die, in accordance with embodiments described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of the invention, the integrated circuit die of the communication chip may comprise strain absorbing layers surrounding surfaces of the die, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate; a die on the package substrate, wherein the die is attached to the package substrate by a die attach film; a sidewall bumper surrounding sidewalls of the die; and a mold layer over the die and the package substrate.

Example 2: the electronic package of Example 1, wherein a top surface of the sidewall bumper is substantially coplanar with a top surface of the die.

Example 3: the electronic package of Example 1 or Example 2, wherein the top surface of the die is wire bonded to the package substrate.

Example 4: the electronic package of Examples 1-3, wherein the die attach film contacts a bottom surface of the die and a bottom surface of the sidewall bumper.

Example 5: the electronic package of Examples 1-4, further comprising a top surface bumper over a top surface of the die.

Example 6: the electronic package of Examples 1-5, wherein the die is separated from the mold layer by the sidewall bumper and the top surface bumper.

Example 7: the electronic package of Examples 1-6, further comprising a plurality of dies, wherein each die is surrounded by a sidewall bumper.

Example 8: the electronic package of Examples 1-7, wherein the dies are memory dies.

Example 9: the electronic package of Examples 1-8, wherein the sidewall bumper has a thickness greater than 15 microns.

Example 10: the electronic package of Examples 1-9, wherein the sidewall bumper has a thickness that is greater than a thickness of the die attach film.

Example 11: the electronic package of Examples 1-10, wherein the sidewall bumper has a modulus that is less than the modulus of the mold layer.

Example 12: a semiconductor die module, comprising: a semiconductor die having a first surface, a second surface opposite the first surface and a sidewall surface coupling the first surface to the second surface; a sidewall bumper over the sidewall surface; and a die attach film over the first surface.

Example 13: the semiconductor die module of Example 12, wherein the sidewall bumper is supported on the die attach film.

Example 14: the semiconductor die module of Example 12 or Example 13, wherein the second surface of the semiconductor die is substantially coplanar with a top surface of the sidewall bumper.

Example 15: the semiconductor die module of Examples 12-14, further comprising: a plurality of conductive pads on the second surface of the semiconductor die.

Example 16: the semiconductor die module of Examples 12-15, wherein a thickness of the sidewall bumper is 15 microns or greater.

Example 17: the semiconductor die module of Examples 12-16, wherein the thickness of the sidewall bumper is greater than a thickness of the die attach film.

Example 18: the semiconductor die module of Examples 12-17, further comprising: a second bumper over a portion of the second surface.

Example 19: the semiconductor die module of Examples 12-18, wherein the second bumper does not cover the entire second surface.

Example 20: the semiconductor die module of Examples 12-19, wherein the second bumper is the same material as the sidewall bumper.

Example 21: the semiconductor die module of Examples 12-20, wherein a thickness of the sidewall bumper is greater than a thickness of the second bumper.

Example 22: a method of forming an electronic package, comprising: placing a die substrate onto a carrying tape, wherein the die substrate is attached to the carrying tape by a die attach film; dicing the die substrate to singulate a plurality of dies; expanding the carrying tape to increase a spacing between the plurality of dies; disposing a bumper layer between the plurality of dies, wherein the bumper layer is disposed along sidewall surfaces of the dies; and dicing the bumper layer to form a plurality of dies where each die includes a bumper layer along the sidewall surfaces of the dies.

Example 23: the method of Example 22, further comprising: stacking a plurality of the dies onto a package substrate; and wire bonding the plurality of dies to the package substrate.

Example 24: the method of Example 22 or Example 23, further comprising: disposing a second bumper layer over exposed top surfaces of the plurality of dies.

Example 25: the method of Examples 22-24, further comprising: disposing a mold layer over the plurality of dies, wherein the mold layer is separated from the plurality of dies by the bumper layers and the second bumper layers

What is claimed is:

1. An electronic package, comprising:
a package substrate;
a die on the package substrate, wherein the die is attached to the package substrate by a die attach film;
a sidewall bumper surrounding sidewalls of the die; and
a mold layer over the die and the package substrate.

2. The electronic package of claim 1, wherein a top surface of the sidewall bumper is substantially coplanar with a top surface of the die.

3. The electronic package of claim 2, wherein the top surface of the die is wire bonded to the package substrate.

4. The electronic package of claim 1, wherein the die attach film contacts a bottom surface of the die and a bottom surface of the sidewall bumper.

5. The electronic package of claim 1, further comprising a top surface bumper over a top surface of the die.

6. The electronic package of claim 5, wherein the die is separated from the mold layer by the sidewall bumper and the top surface bumper.

7. The electronic package of claim 1, further comprising a plurality of dies, wherein each die is surrounded by a sidewall bumper.

8. The electronic package of claim 7, wherein the dies are memory dies.

9. The electronic package of claim 1, wherein the sidewall bumper has a thickness greater than 15 microns.

10. The electronic package of claim 1, wherein the sidewall bumper has a thickness that is greater than a thickness of the die attach film.

11. The electronic package of claim 1, wherein the sidewall bumper has a modulus that is less than the modulus of the mold layer.

12. A semiconductor die module, comprising:
a semiconductor die having a first surface, a second surface opposite the first surface and a sidewall surface coupling the first surface to the second surface;
a sidewall bumper over the sidewall surface; and
a die attach film over the first surface.

13. The semiconductor die module of claim 12, wherein the sidewall bumper is supported on the die attach film.

14. The semiconductor die module of claim 12, wherein the second surface of the semiconductor die is substantially coplanar with a top surface of the sidewall bumper.

15. The semiconductor die module of claim 12, further comprising:
a plurality of conductive pads on the second surface of the semiconductor die.

16. The semiconductor die module of claim 12, wherein a thickness of the sidewall bumper is 15 microns or greater.

17. The semiconductor die module of claim 16, wherein the thickness of the sidewall bumper is greater than a thickness of the die attach film.

18. The semiconductor die module of claim 12, further comprising:
a second bumper over a portion of the second surface.

19. The semiconductor die module of claim 18, wherein the second bumper does not cover the entire second surface.

20. The semiconductor die module of claim 18, wherein the second bumper is the same material as the sidewall bumper.

21. The semiconductor die module of claim 18, wherein a thickness of the sidewall bumper is greater than a thickness of the second bumper.

22. A method of forming an electronic package, comprising:
placing a die substrate onto a carrying tape, wherein the die substrate is attached to the carrying tape by a die attach film;
dicing the die substrate to singulate a plurality of dies;
expanding the carrying tape to increase a spacing between the plurality of dies;
disposing a bumper layer between the plurality of dies, wherein the bumper layer is disposed along sidewall surfaces of the dies; and
dicing the bumper layer to form a plurality of dies where each die includes a bumper layer along the sidewall surfaces of the dies.

23. The method of claim 22, further comprising:
stacking a plurality of the dies onto a package substrate; and
wire bonding the plurality of dies to the package substrate.

24. The method of claim 23, further comprising:
disposing a second bumper layer over exposed top surfaces of the plurality of dies.

25. The method of claim 24, further comprising:
disposing a mold layer over the plurality of dies, wherein the mold layer is separated from the plurality of dies by the bumper layers and the second bumper layers.
